(19) United States
(12) Patent Application Publication
(10) Pub. No.: US 2014/0151710 A1
(43) Pub. Date: Jun. 5, 2014

(54) Stacked Gate Structure, Metal-Oxide-Semiconductor Including the Same, and Method for Manufacturing the Stacked Gate Structure

(71) Applicant: NATIONAL CHIAO TUNG UNIVERSITY, Hsinchu City (TW)

(72) Inventors: Yueh-Chin LIN, Hsinchu City (TW); Edward Yi CHANG, Hsinchu County (TW); Ting-Wei CHUANG, Chiayi County (TW)

(73) Assignee: NATIONAL CHIAO TUNG UNIVERSITY, Hsinchu City (TW)

(21) Appl. No.: 13/789,690

(22) Filed: Mar. 8, 2013

(30) Foreign Application Priority Data
Dec. 3, 2012 (TW) 101145311

(51) Int. Cl. H01L 29/78; H01L 21/28

(52) U.S. Cl. CPC H01L 29/78; H01L 21/28008
USPC 257/76; 257/411; 438/591

(57) ABSTRACT

The invention provides a stacked gate structure and metal-oxide-semiconductor including the same, and method for manufacturing the stacked gate structure. The stacked gate structure comprises a substrate, a semiconductor layer positioned on the substrate, a gate dielectric positioned on the semiconductor layer, and a gate electrode layer positioned on the gate dielectric, which the gate dielectric comprises a composite oxide layer composed of lanthanum oxide (La₂O₃) and hafnium oxide (HfO₂).

### RELATED APPLICATIONS

This application claims priority to Taiwan Application Serial Number 101145311 filed Dec. 3, 2012, which is herein incorporated by reference.

### BACKGROUND

1. Technical Field

The present disclosure relates to a stacked gate structure, and more particularly, to a stacked gate structure having a dielectric layer composed of hafnium oxide (HfO₂) and lanthanum oxide (La₂O₃).

2. Description of Related Art

For gate dielectric in a complementary metal oxide semiconductor (CMOS) processing, the performance and reliability are the essential concerns all the time. The concerns are particularly significant in use of a high-k dielectric material (the dielectric content is greater than 3.9, such as silicon oxide), in that the silicon oxide layer made thereof has a thinner equivalent oxide thickness (EOT) with respect to that of the conventional silicon oxide layer. With the increasing demand on capacitance per unit area in the manufacture of integrated circuit, the development of dielectric materials having even higher k constant never stops. However, in that the undesired diffusion occurs between high-k dielectrics and the underlying semiconductor, the carrier mobility of the semiconductor degrades. Concerning the undesired diffusion, a silicon oxide layer, in addition to the high-k dielectrics, is typically formed between the high-k dielectrics and the underlying semiconductor, so as to avoid the diffusion of the high-k dielectrics in the gate of a semiconductor element.

Given the above, on the one hand the conventional silicon oxide layer is insufficient to reduce the EOT; on the other hand the silicon oxide of higher k is able to reduce the thickness but also to introduce the undesired diffusion between the high-k dielectrics and the underlying semiconductor, which may fail the semiconductor element. Therefore, an improved gate structure and a method of manufacturing the same are needed, so as to solve the aforementioned problems.

### SUMMARY

The present disclosure provides a stacked gate structure using high-k dielectric material as a gate dielectric layer and a method for manufacturing thereof, so as to solve the problems of the prior art and achieve better performance.

One aspect of the present disclosure is to provide a stacked gate structure. The stacked gate structure comprises a substrate, a semiconductor layer positioned on the substrate, a gate dielectric positioned on the semiconductor layer, and a gate electrode layer positioned on the gate dielectric. In which, the gate dielectric comprises a composite oxide layer composed of lanthanum oxide (La₂O₃) and hafnium oxide (HfO₂)

Another aspect of the present disclosure is to provide a method for manufacturing the stacked gate structure. The method for manufacturing the stacked gate structure comprises the following steps. A semiconductor layer is provided having a first surface and a second surface; a plurality of hafnium oxide layers and lanthanum oxide layers are formed on the first surface of the semiconductor layer; a composite oxide layer of a gate dielectric is formed by conducting rapid-thermal annealing of the hafnium oxide layers and the lanthanum oxide layers; a gate electrode layer is formed on the gate dielectric, an ohmic contact layer is formed in contact with the second surface of the semiconductor layer; and a back metal layer is formed in contact with the ohmic contact layer, but not with the semiconductor layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a stacked gate structure 100 according to one embodiment of the present disclosure;

FIG. 2A to 2G are cross-sectional views of making a stacked gate structure according to one embodiment of the present disclosure;

FIG. 3A is a line chart of gate voltage to the capacitance value of the gate dielectric layer according to one embodiment of the present disclosure, in which the horizontal axis is gate voltage (V), and the vertical axis is capacitance per unit area (mF/cm²);

FIG. 3B is a line chart of gate voltage to the capacitance value of the gate dielectric layer according to one embodiment of the present disclosure, in which the horizontal axis is gate voltage (V), and the vertical axis is capacitance per unit area (mF/cm²);

FIG. 4A is a SEM photograph (left) and an elemental distribution diagram (right) of a conventional stacked gate structure, in which the scale is 2 nm; and

FIG. 4B is a SEM photograph (left) and an elemental distribution diagram (right) of the stacked gate structure according to one embodiment of the present disclosure, in which the scale is 5 nm.

### DETAILED DESCRIPTION

The stacked gate structure and the method for manufacturing the same of the embodiments are discussed in detail below, but not limited the scope of the present disclosure. The same symbols or numbers are used to the same or similar portion in the drawings or the description. And the applications of the present disclosure are not limited by the following embodiments and examples, which the person in the art can apply in the related field.

The present disclosure provides a stacked gate structure using high-k materials as a gate dielectric, and a method for manufacturing thereof. In which, the gate dielectric comprises a composite oxide layer composed of lanthanum oxide (La₂O₃) and hafnium oxide (HfO₂).

Table 1 lists the dielectric coefficients and energy band-gap values (Eg) of the conventional oxides. Since alumina (Al₂O₃) has good energy band-gap value and dielectric coefficient higher than silicon oxide, it is normally applied to the III-V semiconductor device. Hafnium oxide (HfO₂) has the dielectric coefficient of 25 and the energy band-gap value of up to 57 eV. And lanthanum oxide (La₂O₃) has the higher dielectric coefficient of 30 and the energy band-gap value of 4.3 eV.

TABLE 1

| | Hafnium oxide | Lanthanum oxide | Alumina |
|---|---|---|---|
| Metal Oxide | (HfO₂) | (La₂O₃) | (Al₂O₃) |
| Dielectric | 25 | 30 | 8-11.5 |
| coefficient (k) | | | |
| Energy band-gap | 5.7 | 4.3 | 6.65 |
| value (eV) | | | |

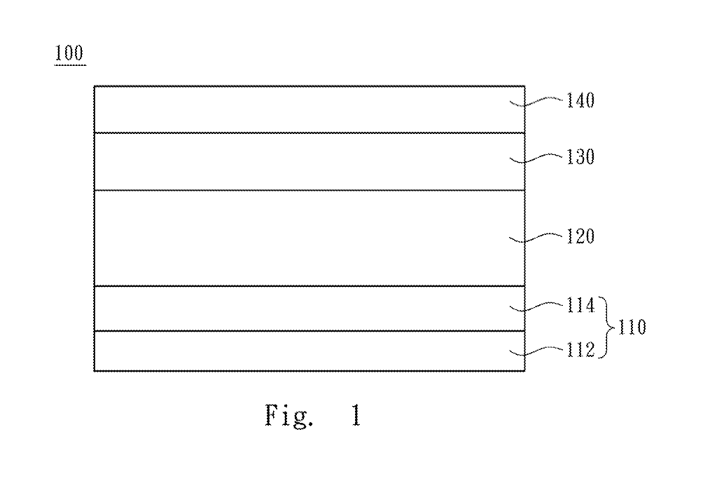

FIG. 1 is a cross-sectional view of a stacked gate structure 100 according to one embodiment of the present disclosure. In FIG. 1, the semiconductor layer 120 is positioned on the substrate 110. The gate dielectric 130 is positioned on the semiconductor layer 120, in which the gate dielectric 130 comprises a composite oxide layer composed of lanthanum oxide (La₂O₃) and hafnium oxide (HfO₂). And the gate electrode layer 140 is positioned on the gate dielectric 130. According to one embodiment of the present disclosure, the substrate 110 further comprises the back metal layer 112, and the ohmic contact layer 114 is interposed between the back metal layer 112 and the semiconductor layer 120.

According to one embodiment of the present disclosure, the semiconductor layer 120 is III-V semiconductor. According to other embodiments of the present disclosure, the material of the semiconductor 120 comprises Indium gallium arsenide (InGaAs), indium arsenide (InAs), indium aluminum arsenide (InAlAs), indium phosphide (InP), gallium arsenide (GaAs), indium antimonide (InSb), indium gallium antimonide (lnGaSb), gallium nitride (GaN) or aluminum gallium arsenide (AlGaAs)

According to one embodiment of the present disclosure, the dielectric coefficient of the gate dielectric 130 is higher than 27. According to another one embodiment of the present disclosure, the thickness of the gate dielectric 130 is about 4 nm to 15 nm, preferably about 6 nm to 12 nm, and more preferably about 8 nm to 10 nm.

According to one embodiment of the present disclosure, the material of the gate dielectric layer 140 is selected from the group of nickel (Ni), gold (Au), to titanium (Ti), platinum (Pt), copper (Cu), aluminum (Al), tantalum nitride (TaN), and combinations thereof.

According to one embodiment of the present disclosure, the stacked gate structure 100 is used for capacitors or field effect transistors.

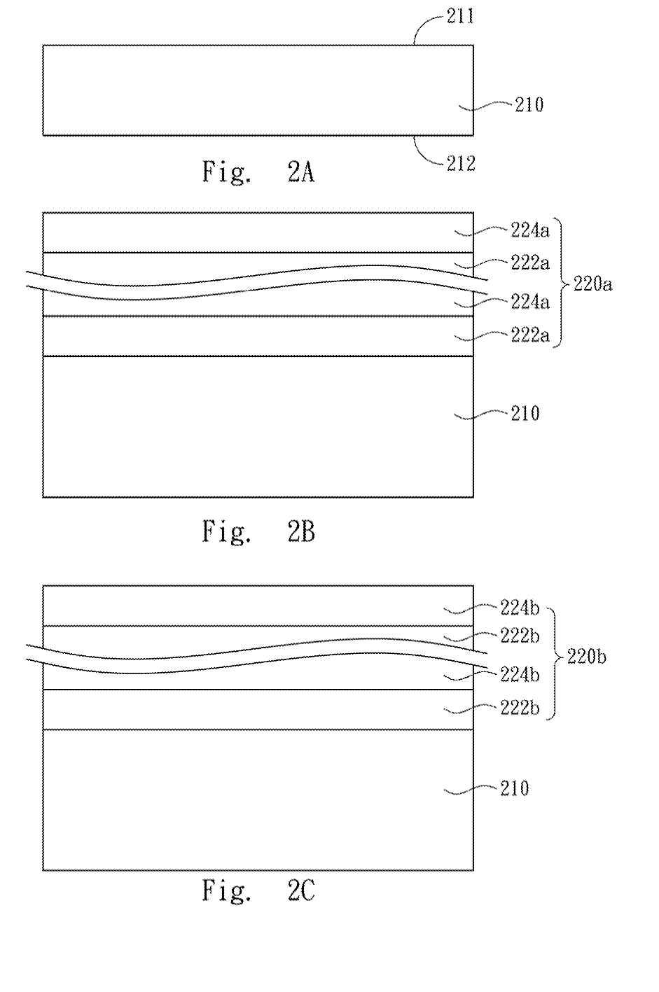

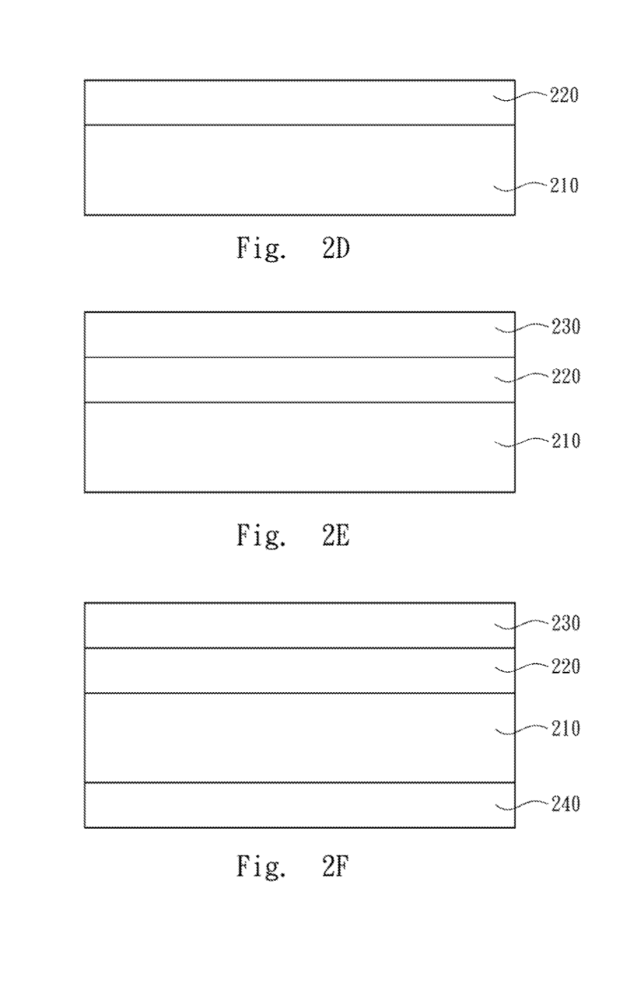

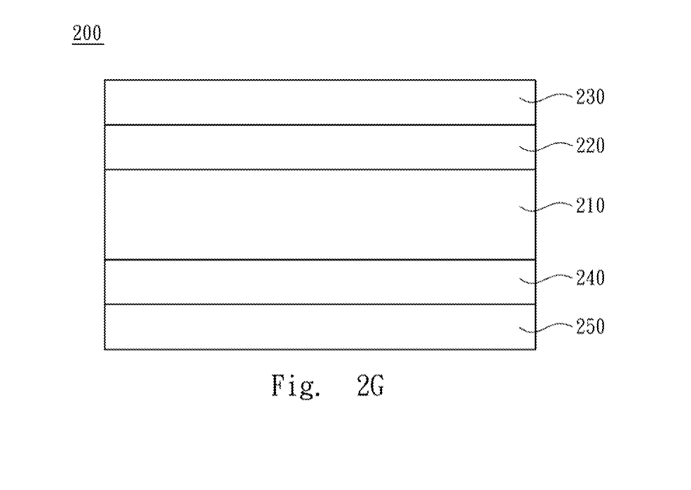

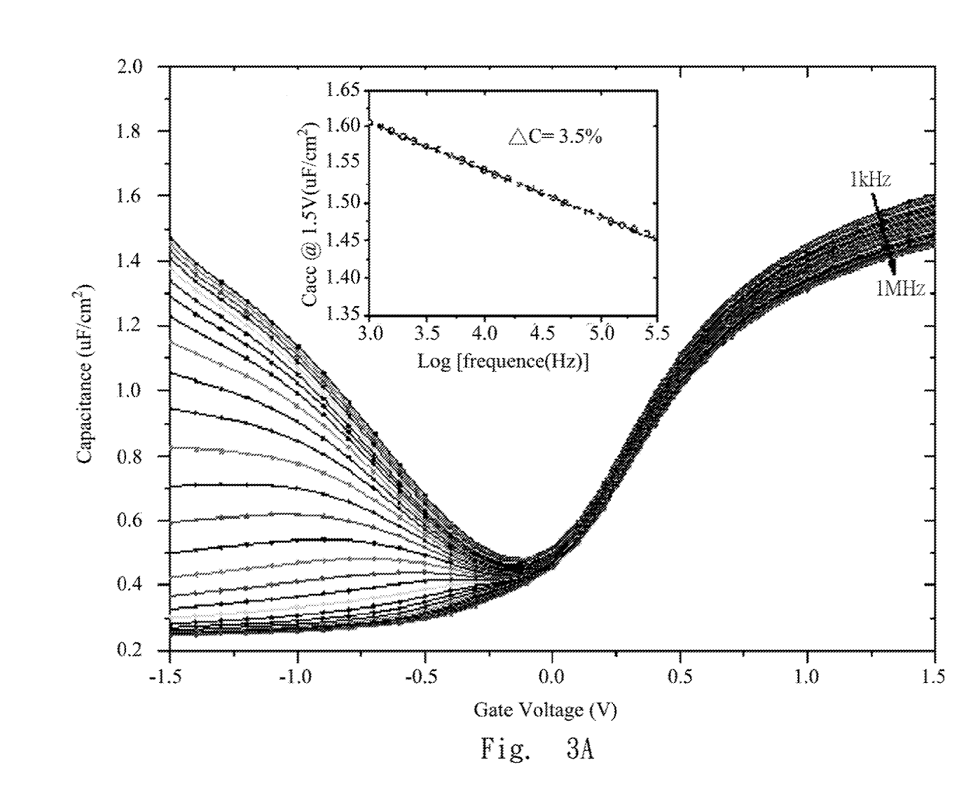

FIG. 2A to 2G are cross-sectional views of making a stacked gate structure according to one embodiment of the present disclosure. First, the semiconductor layer 210 is provided, and has the first surface 211 and the second surface 212, shown as FIG. 2A. Then, a plurality of hafnium oxide layers and lanthanum oxide layers is formed on the first surface of the semiconductor layer, in which the hafnium oxide layers and the lanthanum oxide layers are alternatively stacked. According to one embodiment of the present disclosure, a hafnium oxide layer 222a is formed on the first surface 211 of the semiconductor layer 210, and then a lanthanum oxide layer 224a is formed on the hafnium oxide layer 222a, in this order to form an oxide layer 220a alternatively stacked with a plurality of hafnium oxide layers 222a and lanthanum oxide layers 224a, shown as FIG. 28. According to another one embodiment of the present disclosure, a lanthanum oxide layer 222b is formed on the first surface 211 of the semiconductor layer 210, and then a hafnium oxide layer 224b is formed on the lanthanum oxide layer 222b, such that an oxide layer 220b is alternatively stacked with sequential multiple lanthanum oxide layers 222b and hafnium oxide layers 224b, shown as FIG. 2C.

In FIG. 2B or FIG. 2C, the method for forming the oxide layer 220a or 220b comprises remote plasma CVD (RPCVD), plasma enhanced CVD (PECVD), atomic layer deposition (ALD), MOCVD, MBE, PVD, sputtering or other methods known in the art.

According to one embodiment of the present disclosure, the thickness of the hafnium oxide 222a or 224b is 0.5 nm to 2.0 nm. According to another one embodiment of the present disclosure, the thickness of the hafnium oxide 222a or 224b is 0.8 nm to 1.5 nm.

According to one embodiment of the present disclosure, the thickness of the lanthanum oxide 224a or 222b is 0.5 nm to 2.0 nm. According to another one embodiment of the present disclosure, the thickness of the lanthanum oxide 224a or 222b is 0.8 nm to 1.5 nm.

In FIG. 2D, by a post-deposition annealing (PDA), the oxide layer 220a or 220b of FIG. 2B or 2C interacts with the first surface 211 of the semiconductor layer 210, so as to form a composite oxide layer. In which, the composite oxide layer is used as gate dielectric 220. According to one embodiment of the present disclosure, the thickness of the gate dielectric 220 is about 4 nm to 15 nm, preferably about 6 nm to 12 nm, and more preferably about 8 nm to 10 nm, so as to maintain low interface state density (Dᵢₜ) and thinner equivalent oxide thickness (EOT). According to another one embodiment of the present disclosure, the temperature of the post-deposition annealing to form the composite oxide layer is about 500° C.

In FIG. 2E, the gate electrode layer 230 is formed on the gate dielectric 220. According to one embodiment of the present disclosure, the gate electrode layer 230 is composed of nickel (Ni), gold (Au), titanium (Ti), platinum (Pt), copper (Cu), aluminum (Al), tantalum nitride (TaN), or combinations thereof by the E-gun process.

Then, the ohmic contact layer 240 is formed to contact with the second surface 212 of the semiconductor layer 210, shown as FIG. 2F. According to one embodiment of the present disclosure, the material of the ohmic contact layer 240 comprises indium phosphide (InP).

In FIG. 2G, the back metal layer 250 is formed in contact with the ohmic contact layer 240, but not with the semiconductor layer 210, so as to form the stacked gate structure 200. According to one embodiment of the present disclosure, the material of the back metal layer 250 is selected from the group of gold (Au), germanium (Ge), nickel (Ni), and combinations thereof.

Table 2 exhibits the comparison of the embodiments in the present disclosure, including the effect of the oxide composition of different gate dielectric and thermal annealing temperature for the stacked gate structure.

TABLE 2

| | | | Capaci- | | |
|---|---|---|---|---|---|
| | | | tance | | Interface |
| | Oxide | Thermal | equivalent | | state |
| | composition | annealing | thickness | Diffu- | density |
| | of gate | temperature | at 1 kHz | sivity | (Dᵢₜ, ×10¹¹ |
| | dielectric | (° C.) | (nm) | (%) | cm⁻²eV⁻¹) |
| Comparative | Hafnium | 500 | 2.7 | 5.1 | 24.0 |
| Example 1 | oxide (total | | | | |
| | thickness | | | | |
| | of 8 nm) | | | | |
| Embodiment | Hafnium | 400 | — | — | 251.0 |
| 1 | oxide | 500 | 2.2 | 3.5 | 7.2 |
| | (0.8 nm)/ | 550 | 2.2 | 3.5 | 9.5 |
| | lanthanum | | | | |
| | oxide | | | | |
| | (0.8 nm) × 5 | | | | |
| | (total | | | | |
| | thickness | | | | |
| | of 8 nm) | | | | |
| Embodiment | Lanthanum | 400 | 2.3 | 4.2 | 29.2 |
| 2 | oxide | 500 | 2.3 | 2.8 | 9.7 |
| | (0.8 nm)/ | 550 | 2.5 | 4.2 | 17.7 |
| | hafnium | | | | |
| | oxide | | | | |
| | (0.8 nm) × 5 | | | | |
| | (total | | | | |
| | thickness | | | | |
| | of 8 nm) | | | | |

In Comparative Example 1, the oxide layer of the gate dielectric is hafnium oxide, and the total thickness of which is 8 nm. The gate dielectric is formed by post-deposition annealing at 500° C., and the capacitance equivalent thickness at 1 kHz of 21 nm, the diffusivity of 5.1%, and the interface state density (Dᵢₜ) of 24.0×10¹¹ cm⁻²eV⁻¹.

In Embodiment 1, the oxide composition of the gate dielectric is shown as FIG. 2B. The hafnium oxide layer is firstly formed on the semiconductor layer, and then the lanthanum oxide layer is formed on the hafnium oxide layer, in this order to form a composite oxide layer staggered and stacked by 5 hafnium oxide layers and 5 lanthanum oxide layers. In which, hafnium oxide (thickness of 0.8 nm per layer) and lanthanum oxide (thickness of 0.8 nm per layer) are 10 layers, and the total thickness is 8 nm. From Table 2, in the composite oxide layer of Embodiment 1 under post-deposition annealing at 500° C., the gate dielectric has the lowest interface state density (7.2×10¹¹ cm⁻² eV⁻¹), the capacitance equivalent thickness at 1 kHz of 2.2 nm, and the diffusivity of 3.5%.

In Embodiment 2, the oxide composition of the gate dielectric is shown as FIG. 2C. The lanthanum oxide layer is firstly formed on the semiconductor layer, and then the hafnium oxide layer is formed on the lanthanum oxide layer, in this order to form a composite oxide layer alternatively stacked with five lanthanum oxide layers and five hafnium oxide layers. In which, lanthanum oxide (thickness of 0.8 nm per layer) and hafnium oxide (thickness of 0.8 nm per layer) are ten layers, and the total thickness is 8 nm. From Table 2, in the composite oxide layer of Embodiment 2 under post-deposition annealing at 500° C., the gate dielectric has the lowest interface state density (9.7×10¹¹ cm⁻²eV⁻¹), the capacitance equivalent thickness at 1 kHz of 2.3 nm, and the diffusivity of 2.8%.

Comparing the Comparative Example 1, Embodiment 1 and Embodiment 2 on Table 2, the gate structures made of the oxides all have lower interface state density (Dᵢₜ), so as to enhance the performance of semiconductor elements. However, compared to Comparative Example 1, Embodiment 1 and 2 all have the lower diffusivity. Although the energy band-gap value of lanthanum oxide is lower than hafnium oxide, the gate structure, formed by the composite oxide layer in the present disclosure composed of hafnium oxide and lanthanum oxide, has the lower diffusivity than that of the gate structure formed by hafnium oxide only, and not easily disperse into the semiconductor layer. Thus, the semiconductor elements have higher electrical stability. Otherwise, Embodiment 1 and 2 also have thinner capacitance equivalent thickness at 1 kHz, so as to reduce the total thickness of the semiconductor elements. And the results of Embodiment 1 and 2 are shown that, the formation order of hafnium oxide and lanthanum oxide has no effect on the diffusivity of the composite oxide layer in the present disclosure.

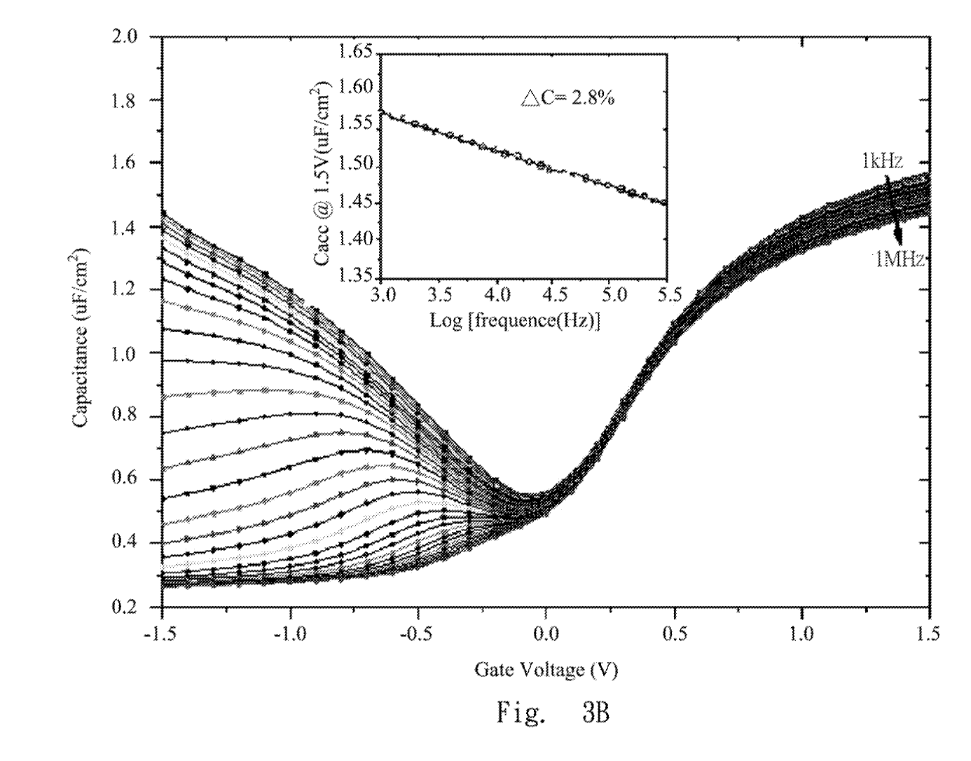

FIG. 3A is a line chart of gate voltage to the capacitance value of the gate dielectric layer according to one embodiment of the present disclosure, in which the horizontal axis is gate voltage (V), and the vertical axis is capacitance per unit area (mF/cm²). And FIG. 3B is a line chart of gate voltage to the capacitance value of the gate dielectric layer according to one embodiment of the present disclosure, in which the horizontal axis is gate voltage (V), and the vertical axis is capacitance per unit area (mF/cm²). FIGS. 3A and 38 have similar relationship between gate voltage and capacitance, and this result shows that the formation order of hafnium oxide and lanthanum oxide has no significant effect on the electrical relationship of the stacked gate structure.

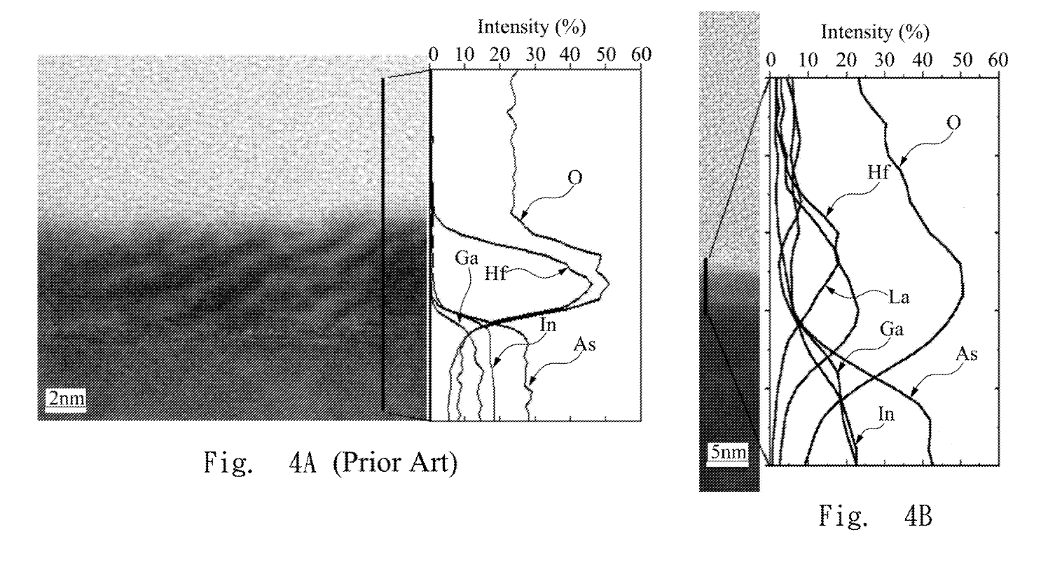

FIG. 4A is a SEM photograph (left) and an elemental distribution diagram (right) of a conventional stacked gate structure, in which the scale is 2 nm. FIG. 4B is an SEM photograph (left) and an elemental distribution diagram (right) of the stacked gate structure according to one embodiment of the present disclosure, where the scale is 5 nm. Compared with FIG. 4A, the element distribution of the stacked gate structure in FIG. 4B is more concentrated. This result is shown that the elements of gate dielectric do not easily disperse to semiconductor layer, and the elements of semiconductor layer do not also disperse to gate dielectric. The stacked gate structure in FIG. 4B has the best structural stability, so as to enhance the performance of semiconductor elements.

Although embodiments of the present disclosure and their advantages have been described in detail, they are not used to limit the present disclosure. It should be understood that various changes, substitutions and alterations can be made herein without departing from the spirit and scope of the present disclosure. Therefore, the protecting scope of the present disclosure should be defined as the following claims.

1. A stacked gate structure of a transistor, comprising:
a substrate;
a semiconductor layer positioned on the substrate;
a gate dielectric layer positioned on the semiconductor layer, wherein the gate dielectric layer comprises a composite oxide layer composed of lanthanum oxide (La₂O₃) and hafnium oxide (HfO₂); and
a gate electrode layer positioned on the gate dielectric layer.

2. The stacked gate structure of claim 1, wherein the semiconductor layer is a III-V semiconductor.

3. The stacked gate structure of claim 1, wherein the material of the semiconductor layer comprises Indium gallium arsenide (InGaAs), indium arsenide (InAs), indium aluminum arsenide (InAlAs), indium phosphide (InP), gallium arsenide (GaAs), indium antimonide (InSb), indium gallium antimonide (InGaSb), gallium nitride (GaN) or aluminum gallium arsenide (AlGaAs).

4. The stacked gate structure of claim 1, wherein the dielectric constant of the gate dielectric layer is greater than 27.

5. The stacked gate structure of claim 1, wherein the thickness of the gate dielectric layer is in a range of 4 nm to 15 nm.

6. The stacked gate structure of claim 1, wherein the thickness of the gate dielectric layer is in a range of 6 nm to 12 nm.

7. The stacked gate structure of claim 1, wherein the material of the gate electrode layer is selected from the group consisting of nickel (Ni), gold (Au), titanium (Ti), platinum (Pt), copper (Cu), aluminum (Al), tantalum nitride (TaN), and a combination thereof.

8. A method for manufacturing a stacked gate structure of a transistor, comprising the steps of:
providing a semiconductor layer having a first surface and a second surface;
forming a plurality of hafnium oxide layers and lanthanum oxide layers on the first surface of the semiconductor layer;
conducting rapid thermal annealing of the hafnium oxide layers and lanthanum oxide layers to form a gate dielectric layer having a composite oxide layer;
forming a gate electrode layer on the gate dielectric layer;
forming an ohmic contact layer in contact with the second surface of the semiconductor; and
forming a back-metal layer in contact with the ohmic contact layer, but not with the semiconductor layer.

9. The method of claim 8, wherein the hafnium oxide layers and lanthanum oxide layers are alternatively stacked on the first surface of the semiconductor.

10. The method of claim 8, wherein the thickness of the hafnium oxide layers is in a range of 0.5 nm to 2.0 nm.

11. The method of claim 8, wherein the thickness of the hafnium oxide layers is in a range of 0.8 nm to 1.5 nm.

12. The method of claim 8, wherein the thickness of the lanthanum oxide layers is in a range of 0.5 nm to 2.0 nm.

13. The method of claim 8, wherein the thickness of the lanthanum oxide layers is in a range of 0.8 nm to 1.5 nm.
